(19) United States
(12) Patent Application Publication
(10) Pub. No.: US 2026/0124946 A1
(43) Pub. Date: May 7, 2026

(54) DEVICE AND METHOD FOR SCHEDULING CHARGING AND DISCHARGING OF ELECTRIC VEHICLE

(71) Applicants: HYUNDAI MOTOR COMPANY, Seoul (KR); KIA CORPORATION, Seoul (KR)

(72) Inventors: Jeong Hoon Choi, Hwaseong-si (KR); Hyun Sup Kim, Hwaseong-si (KR); Min Kyu Lee, Hwaseong-si (KR); Jae Yun Jung, Hwaseong-si (KR); Na Yeon Park, Hwaseong-si (KR); Dae Gun Ko, Hwaseong-si (KR); Hye Seung Han, Hwaseong-si (KR); Sung Kyu Kim, Hwaseong-si (KR); Bum Su Park, Hwaseong-si (KR)

(73) Assignees: HYUNDAI MOTOR COMPANY, Seoul (KR); KIA CORPORATION, Seoul (KR)

(21) Appl. No.: 19/202,729

(22) Filed: May 8, 2025

(30) Foreign Application Priority Data
Nov. 1, 2024 (KR) 10-2024-0153331

(51) Int. Cl. B60L 53/62; B60L 53/14; B60L 53/68; G06Q 10/1093

(52) U.S. Cl. CPC B60L 53/62; B60L 53/68; G06Q 10/1097; B60L 53/14

(57) ABSTRACT

A device for scheduling charging and discharging of an electric vehicle is provided. The device includes one or more processors, and a memory configured to store one or more programs executed by the one or more processors. The processor is configured to calculate a first charging and discharging schedule so that a state of charge (SOC) at a time point when the electric vehicle exits is higher than or equal to a target SOC according to electric vehicle information, and calculate a second charging and discharging schedule for participation in an electric power market according to contracted power capacity data received from a demand management business operator server based on the first charging and discharging schedule.

### CROSS-REFERENCE TO RELATED APPLICATION(S)

This application claims priority to and the benefit of Korean Patent Application No. 10-2024-0153331, filed on Nov. 1, 2024, the disclosure of which is incorporated herein by reference in its entirety.

### TECHNICAL FIELD

Embodiments relate to a device and method for scheduling charging and discharging of an electric vehicle.

### BACKGROUND

As the spread of various distributed energy resources such as solar power generation, wind power generation, and an energy storage system (ESS) are actively progressing, a vehicle to grid (V2G) technology, which provides discharging in addition to charging by sending the energy of an electric vehicle battery to a power grid, is being considered. In addition, a technology that uses the V2G technology to reduce an electricity bill and generate profits in connection with homes (e.g., vehicle to home (V2H)), buildings (vehicle to building (V2B)), or the like and further contributes to the stabilization of the power grid is being considered.

Accordingly, the management of charging and discharging scheduling of electric vehicles may be useful. Recently, as the spread and sales of electric vehicles increase, variables are increasing, which may cause concerns such as increased calculation dimensions, increased complexity, and, representatively, increased time.

### SUMMARY

The present disclosure is directed to providing a device and method for scheduling charging and discharging of an electric vehicle, which are capable of performing optimal charging and discharging scheduling of an electric vehicle.

In addition, the present disclosure is directed to providing a device and method for scheduling charging and discharging of an electric vehicle, which are capable of participating in an electric power trading market to generate profits using power of an electric vehicle.

According to an aspect of the present disclosure, there is provided a device for scheduling charging and discharging of an electric vehicle, which includes one or more processors, and a memory configured to store one or more programs executed by the one or more processors, wherein the processor is configured to calculate a first charging and discharging schedule so that a state of charge (SOC) at a time point when an electric vehicle exits is higher than or equal to a target SOC according to electric vehicle information, and calculate a second charging and discharging schedule for participation in an electric power market according to contracted power capacity data received from a demand management business operator server based on the first charging and discharging schedule.

The electric vehicle information may include plug-in charger information, a current SOC, a target SOC, resource type information, battery capacity information, battery charging and discharging efficiency, and scheduled vehicle entry time and scheduled vehicle exit time information.

The processor may sum plug-in times from a plurality of scheduled vehicle entry times to a plurality of scheduled vehicle exit times and calculate the first charging and discharging schedule and the second charging and discharging schedule according to the summed plug-in times.

The processor may calculate the second charging and discharging schedule to comply with hourly contracted power capacity.

The second charging and discharging schedule may include a schedule of charging power and discharging power.

The processor may calculate the second charging and discharging schedule so that a total of charging efficiencies is equal to a total of discharging efficiencies.

The processor may calculate the first charging and discharging schedule and the second charging and discharging schedule to limit discharging according to the resource type information.

According to another aspect of the present disclosure, there is provided a method of scheduling charging and discharging of an electric vehicle, which is performed by a computing device including one or more processors and a memory configured to store one or more programs executed by the one or more processors and includes calculating, by the processor, a first charging and discharging schedule so that a state of charge (SOC) at a time point when an electric vehicle exits is higher than or equal to a target SOC according to electric vehicle information, and calculating, by the processor, a second charging and discharging schedule for participation in an electric power market according to contracted power capacity data received from a demand management business operator server based on the first charging and discharging schedule.

The electric vehicle information may include plug-in charger information, a current SOC, a target SOC, resource type information, battery capacity information, and scheduled vehicle entry time and scheduled vehicle exit time information.

The calculating of the first charging and discharging schedule may include calculating maximum hourly charging and discharging energy using output power included in the plug-in charger information and the scheduled vehicle entry time and the scheduled vehicle exit time.

The calculating of the first charging and discharging schedule may include calculating the first charging and discharging schedule using the current SOC, the battery capacity information, and the target SOC of the electric vehicle.

The calculating of the first charging and discharging schedule may include adjusting the SOC of the electric vehicle to be within a preset battery usage range and calculating the first charging and discharging schedule.

The processor may sum plug-in times from a plurality of scheduled vehicle entry times to a plurality of scheduled vehicle exit times and calculate the first charging and discharging schedule and the second charging and discharging schedule according to the summed plug-in times.

The calculating of the second charging and discharging schedule may include calculating the second charging and discharging schedule to comply with hourly contracted power capacity.

The second charging and discharging schedule may include a schedule of charging power and discharging power.

The calculating of the second charging and discharging schedule may include calculating the second charging and discharging schedule so that a total of charging efficiencies is equal to a total of discharging efficiencies.

The processor may calculate the first charging and discharging schedule and the second charging and discharging schedule to limit discharging according to the resource type information.

### BRIEF DESCRIPTION OF THE DRAWINGS

The above and other objects, features and advantages of the present disclosure will become more apparent to those of ordinary skill in the art by describing example embodiments thereof in detail with reference to the accompanying drawings, in which:

FIG. 1 is a view for providing an electric vehicle power management system according to an example embodiment;

FIG. 2 is a configuration block diagram of a device for scheduling charging and discharging of an electric vehicle according to the example embodiment;

FIG. 3 is a view for providing the operation of the device for scheduling charging and discharging of an electric vehicle according to the example embodiment;

FIGS. 4, 5, and 6 are graphs for providing the operation of a processor according to the example embodiment; and

FIG. 7 is a flowchart illustrating a method of scheduling charging and discharging of an electric vehicle according to an example embodiment.

### DETAILED DESCRIPTION

Hereinafter, example embodiments of the present disclosure are described in detail with reference to the accompanying drawings.

However, the technical spirit of the present disclosure is not limited to some of the described embodiments, but may be implemented in various different forms, and one or more of the components among the embodiments may be used by being (e.g., selectively) coupled or substituted without departing from the scope of the technical spirit of the present disclosure.

In addition, terms (e.g., including technical and scientific terms) used in embodiments of the present disclosure may be construed as those generally understood by those skilled in the art to which the present disclosure pertains unless (e.g., specifically) defined and described, and the commonly used terms, such as terms defined in a dictionary, may be construed in consideration of contextual meanings of related technologies.

In addition, the terms used in the embodiments of the present disclosure are for describing the embodiments and are not intended to limit the present disclosure.

In the specification, a singular form may include a plural form unless otherwise specified in the phrase, and when described as “at least one (or one or more) of A, B, and C,” one or more among (e.g., all) possible combinations of A, B, and C may be included.

In addition, terms such as first, second, A, B, (a), and (b) may be used to describe components of the embodiments of the present disclosure.

These terms are for the purpose of distinguishing one component from another component, and the nature, sequence, order, or the like of the corresponding components is not limited by these terms.

In addition, when a first component is described as being “connected,” “coupled,” or “joined” to a second component, it may include a case in which the first component is (e.g., directly) connected, coupled, or joined to the second component, but also a case in which the first component is “connected,” “coupled,” or “joined” to the second component by other components present between the first component and the second component.

In addition, when the first component is described as being formed or disposed on “on (above) or below (under)” the second component, “on (above)” or “below (under)” may include a case in which two components are in (e.g., direct) contact with each other, and also a case in which one or more third components are formed or disposed between the two components. In addition, when described as “on (above) or below (under),” it may include the meaning of an upward direction and also a downward direction based on one component.

Hereinafter, embodiments will be described in detail with reference to the accompanying drawings, and the same or corresponding components are denoted by the same reference numeral regardless of the reference numerals, and overlapping descriptions thereof may be omitted.

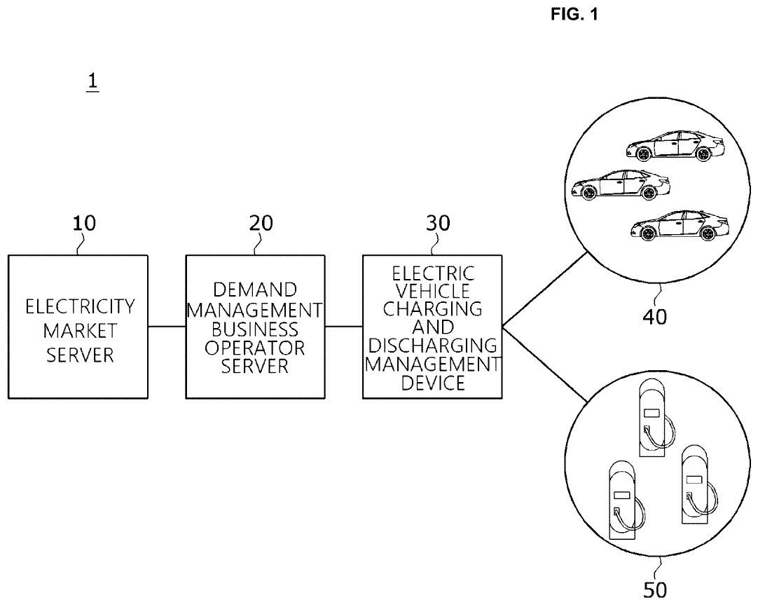

FIG. 1 is a view for describing an electric vehicle power management system according to an example embodiment. Referring to FIG. 1, an electric vehicle power management system 1 may include an electric power market server 10, a demand management business operator server 20, and a device 30 for managing charging and discharging of an electric vehicle.

The electric power market server 10 is a (e.g., main) device that operates an electric power market and may perform settlement according to the participation amount of each resource in different ways according to market settlement rules. The electric power market server 10 may mediate electric power transactions between the demand management business operator servers 20 using electric power transaction request information received from a plurality of demand management business operator servers 20.

The electric power market server 10 may be a server that contracts with a demand management business operator to contract power usage and discharge a (e.g., business) amount and distributes profits to the demand management business operator through demand response and a power unit price for each time period.

The demand management business operator server 20 may perform electric power transaction using charging and discharging information received from the connected device 30 for managing charging and discharging of an electric vehicle, renewable energy generation amount information of a connected renewable energy generation system, and power demand information of a connected system.

In an example embodiment, the demand management business operator may be a business operator who contracts with places that use a large amount of electricity, such as factories, large buildings, parking towers, and/or the like, to perform power consumption reduction or the like according to demand response, thus gaining profits.

An electric power system connected to the demand management business operator may transmit power demand information to the demand management business operator server 20 at a preset cycle, at the request of the demand management business operator server, or as needed. The power demand information may include the hourly power demand amount and the power usage reduction demand amount of the connected system.

The demand management business operator server 20 may respond to a demand response through a power usage reduction request, and also may serve as a power plant that reversely transmits electricity that can be used (e.g., directly) in the system using electric vehicles 40, electric vehicle batteries, an energy storage system (ESS), or the like.

For example, the demand management business operator server 20 may receive a next day's charging and discharging amount of the device 30 for managing charging and discharging of an electric vehicle at a (e.g., specific) time every day, bid the charging and discharging amount to the electric power market server side, receive the contracted amount from the electric power market server 10 according to the preset cycle, and transmit the contracted amount to the device 30 for managing charging and discharging of an electric vehicle.

The device 30 for managing charging and discharging of an electric vehicle may (e.g., directly) manage the electric vehicles 40, charging stations 50 of customers who participate in a vehicle to everything (e.g., V2X) service and receive information on the electric vehicles 40 and chargers, plug-in/out signals, and the like. The device 30 for managing charging and discharging of an electric vehicle may determine a next day's charging and discharging bid amount with the goal of maximizing market participation profits and control the charging and discharging of individual electric vehicles 40 to fulfill the contracted amount.

The device 30 for managing charging and discharging of an electric vehicle may monitor information on the electric vehicles 40 and the charging stations 50 and provide various data for customers. The device 30 for managing charging and discharging of an electric vehicle may perform functions of settling bills, managing a parking space, generating and transmitting charging and discharging control instructions, controlling charging and discharging scenarios, diagnosing a battery state of a vehicle, and the like.

The device 30 for managing charging and discharging of an electric vehicle may include a controller 31.

The electric power system may include, for example, a smart grid-related system such as a substation, an electric power market server, a demand management business operator server, renewable sources, an ESS, and/or the like. The renewable energy sources may be energy sources using wind power, solar power, geothermal heat, waste, and the like. The electric power system may supply power within allowable power (or maximum power) Pmax (or allowable AC current IACmax) range to the charging stations 50 under the control of the controller 31.

In some embodiments, when a plurality of electric vehicles 40 are concentrated on the charging stations 50 in a specific region at the same time, the maximum allowable power of the electric power system may vary. That is, the electric power market server 10, the demand management business operator server 20, or an energy management system (EMS) that controls the operation of the electric power system may increase the power capacity by inputting a reserve power source such as an ESS or a nearby renewable energy source and supply the increased power capacity to the charging stations.

The allowable power may be increased under the control of the controller 31 when the power supplied to the electric vehicles 40 is insufficient due to the charging demand information of each electric vehicle 40 (charging demand amounts of electric vehicle users). That is, the controller 31 may control a switch to additionally connect (input) a renewable energy source (or an ESS) within the electric power system to a substation that supplies power to the charging stations 50 so that the allowable power of the electric power system increases when a charging load (a load of the electric vehicle) of the charging station 50 exceeds the allowable power of the electric power system.

The controller 31 may control the overall operation of the components included in the device 30 for managing charging and discharging of an electric vehicle. The controller 31 is an aggregator and may collect the battery capacity of the electric vehicle 40 connected to the charging station 50 through a wired or wireless communication network, a state of charge (SOC) of the battery of the electric vehicle 40, a rated current flowing through a power line, a rated voltage applied to the power line, or the charging demand information of an electric vehicle user (e.g., an owner). The charging demand information of the electric vehicle user may be transmitted to the controller 31 through a communication device included in each of the charging stations 50 or transmitted to the controller 31 through a communication device such as the user's portable phone.

The controller 31 may exchange information with the electric power system through a wired or wireless communication network and exchange data with the charging station 50 through a LAN connection such as Ethernet, power line communication (PLC), or Wi-Fi, which is a wired or wireless communication network.

Based on real-time information of the electric power system, state information of the electric vehicle 40, and charging demand information of each electric vehicle 40, the controller 31 may control the power of the electric power system to be supplied to the charging station 50 within the allowable power range of the electric power system.

The real-time information of the electric power system may include the allowable power information of the electric power system or the electricity ratio information of the electric power system, the state information of the electric vehicle 40 may include the SOC information of the battery included in each electric vehicle 40, and the charging demand information may include a charging demand time of an electric vehicle user, an scheduled vehicle entry time, an scheduled vehicle exit time, and a charging demand amount (a target SOC).

The charging station 50 may charge the batteries of the plurality of electric vehicles 40. Each of the charging stations 50 may include an AC limiter that performs a current allocation operation for each electric vehicle 40. In addition, each of the charging stations 50 may include a battery management system (BMS) of the electric vehicle 40 and a control module for exchanging information with the controller 31. Under the control of the controller 31, the control module may control the current limiter (the AC limiter) to provide a DC charging current to the battery of each of the electric vehicles 40.

Each of the electric vehicles 40 may include a BMS. The BMS may control a battery charging process. Each of the electric vehicles 40 may serve as an active load that requests power from the device 30 for managing charging and discharging of an electric vehicle for a charging time.

A charger for converting an AC current into a DC current of the electric power system to charge the battery of the electric vehicle 40 may be an on-board charger included in each of the electric vehicles 40 or an off-board charger included in each of the charging stations 50.

The electric vehicle 40 may register on a V2X platform and participate in electric power trading. A user of the electric vehicle 40 may join the platform according to the electric power market in which he or she wants to participate and register an expected vehicle entry and exit schedule for the next day. The electric vehicle 40 may transmit information, such as an expected vehicle plug-in time, an expected vehicle plug-out time, SOC information, available battery capacity, and/or the like, to the electric vehicle charging and discharging management device 30.

The electric vehicle power management system 1 is a centralized control system and may adjust charging and discharging schedules of electric vehicles considering the hourly electric power price, the demand and supply of the electric power system, or the like. However, as the number of electric vehicles that are a control target increases, the amount of computation and complexity for optimal scheduling increases.

The device for scheduling charging and discharging of an electric vehicle according to the embodiment can (e.g., technically) optimize the charging and discharging of such a large-scale electric vehicle fleet. The device for scheduling charging and discharging of an electric vehicle according to the embodiment may be included in the configuration of the electric vehicle charging and discharging management device or provided as a separate device. When the device for scheduling charging and discharging of an electric vehicle is provided as a separate device, a separate wired or wireless communication device may be provided to communicate with an electric vehicle, an external server, a terminal, or the like.

In an embodiment, an example in which the device for scheduling charging and discharging of an electric vehicle is included in the device 30 for managing charging and discharging of an electric vehicle of FIG. 1 will be described.

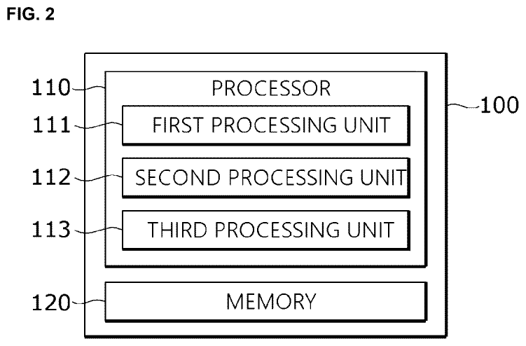

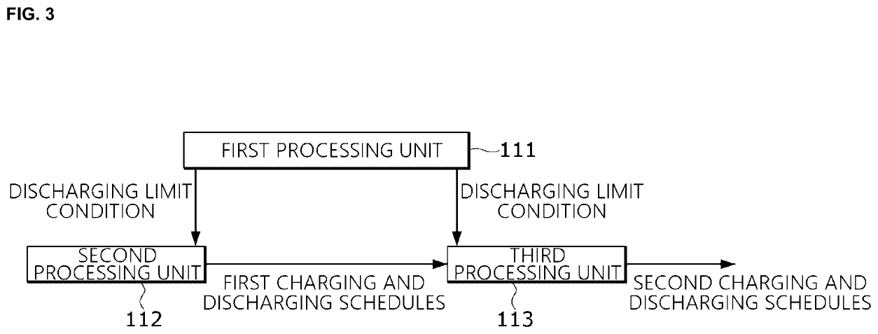

FIG. 2 is a configuration block diagram of a device for scheduling charging and discharging of an electric vehicle according to the example embodiment.

Referring to FIG. 2, the device for scheduling charging and discharging of an electric vehicle 100 may include a processor 110 and a memory 120. In addition, the processor 110 according to the embodiment may include a first processing unit 111, a second processing unit 112, and a third processing unit 113.

The device for scheduling charging and discharging of an electric vehicle 100 according to the embodiment may be implemented in a logic circuit by hardware, firmware, software, or a combination thereof and may also be implemented using a general-purpose or special-purpose computer. The device may be implemented using a hardwired device, a field programmable gate array (FPGA), an application specific integrated circuit (ASIC), and/or the like. In addition, the device for scheduling charging and discharging of an electric vehicle 100 may be implemented as a system on chip (SOC) including one or more processors and controllers.

In addition, the device for scheduling charging and discharging of an electric vehicle 100 may be mounted on a computing device or server, which is provided with hardware elements and in which software, hardware, or a combination thereof is installed. The computing device or the server may be various devices including (e.g., all or some of) a communication device such as a communication modem for communicating with various devices or wired and wireless communication networks, a memory in which data for executing a program is stored, a microprocessor for executing a program to perform calculations and instructions, and the like.

The memory 120 may include a database (DB). The memory 120 may be a non-transitory storage medium for storing instructions executed by the processor. The memory 120 may include at least one of a random access memory (RAM), a static random access memory (SRAM), a read-only memory (ROM), a programmable read-only memory (PROM), an electrically erasable and programmable ROM (EEPROM), an erasable and programmable ROM (EPROM), a hard disk drive (HDD), a solid state disk (SSD), an embedded multimedia card (eMMC), a universal flash storage (UFS), and/or a web storage.

In an embodiment, the first processing unit 111 to the third processing unit 113 may be implemented through the same process, and for convenience of description, the operation of each component is described (e.g., separately) herein below.

The processor 110 may include at least one of processing devices such as an ASIC, a digital signal processor (DSP), a programmable logic device (PLD), an FPGA, a central processing unit (CPU), a microcontroller, and/or a microprocessor.

In addition, each function of the processor may be implemented and operated for each module, and the operation may be determined by turning on/off each module according to the user's settings.

In an embodiment, the device for scheduling charging and discharging of an electric vehicle 100 may receive electric vehicle information through a communication device and store the electric vehicle information in the DB. The electric vehicle information may include plug-in charger information, a current SOC, a target SOC, resource type information, battery capacity information, battery charging and discharging efficiency, and scheduled vehicle entry time and scheduled vehicle exit time information.

The first processing unit 111 may calculate first charging and discharging schedules and second charging and discharging schedules to limit discharging according to the resource type information. The first processing unit 111 may use the resource type information of the electric vehicle information so that the corresponding electric vehicle may partially restrict the charging and discharging function. For example, the first processing unit 111 may calculate the first charging and discharging schedules and the second charging and discharging schedules to limit discharging of an electric vehicle of which resource type information is V1G. In addition, when the resource type information is V2G, the first processing unit 111 may calculate the first charging and discharging schedules and the second charging and discharging schedules so that the corresponding electric vehicle may perform both charging and discharging functions.

In addition, when discharging efficiency is reference efficiency or less according to the charging and discharging efficiency of the battery, the first processing unit 111 may calculate the first charging and discharging schedules and the second charging and discharging schedules to prevent discharging of the corresponding electric vehicle.

The first processing unit 111 may set charging and discharging function limits, transmit the charging and discharging function limits to the second processing unit 112 and the third processing unit 113, and reflect the charging and discharging function limits in the generation of the first charging and discharging schedules and the second charging and discharging schedules.

The second processing unit 112 may calculate the first charging and discharging schedules so that the SOC at a time point when an electric vehicle exits is higher than the target SOC according to the electric vehicle information. The second processing unit 112 may calculate the first charging and discharging schedules using the current SOC, the battery capacity information, and the target SOC of the electric vehicle.

The first charging and discharging schedules may include first charging power and first discharging power.

In this case, the second processing unit 112 may set the first charging and discharging schedules by adjusting the SOC of the electric vehicle to be within a preset battery usage range. When the user participates in the V2X service within a narrower range than default upper and lower limit values of the battery charging amount, this is to guide optimization to be maximized within the corresponding range, and even when a SOC value outside the V2X available range is input or derived, the occurrence of errors in an optimization algorithm can be prevented.

The second processing unit 112 may calculate the maximum hourly charging and discharging energy using the output power included in the plug-in charger information, a scheduled vehicle entry time, and a scheduled vehicle exit time. The second processing unit 112 may be based on the hourly output power value of the charger and may calculate the maximum hourly charging and discharging energy in proportion to the time the electric vehicle maintains the plug-in state. For example, when the maximum hourly output of the charger is 10 [KW] and the plug-in time of the electric vehicle ranges from 10:20 to 15:00, the second processing unit 112 may calculate the maximum charging and discharging energy in a first time slot (10:00 to 11:00) as 40 [min]/60 [min]*10 [KW]=6.67 [kWh] and then calculate the maximum charging and discharging energy from 11:00 to 15:00 as 10 [KW].

The second processing unit 112 may set the first charging and discharging schedules so that the SOC at the scheduled vehicle exit time of the electric vehicle may follow the target SOC according to the maximum hourly charging and discharging energy. The second processing unit 112 may set the first charging and discharging schedules so that the SOC at the scheduled vehicle exit time point of the electric vehicle may follow the target SOC by adapting battery charging and discharging efficiency.

The first charging and discharging schedules may include the charging power amount and discharge strategy amount of the individual electric vehicle. In this case, the second processing unit 112 may determine the charging and discharging power amounts of the individual electric vehicle to follow the target SOC of the individual electric vehicle. The second processing unit 112 may set the first charging and discharging schedules so that a difference value between the SOC of the electric vehicle and the target SOC after actual charging or discharging according to the first charging and discharging schedules is a minimum value. In this case, the second processing unit 112 may set the SOC upper limit value and the SOC lower limit value according to the available capacity range of the battery of the individual electric vehicle and set the first charging and discharging schedules so that the electric vehicle may be charged and discharged within the range of the SOC upper limit value and the SOC lower limit value.

That is, the second processing unit 112 may set the difference value between the SOC of the electric vehicle after the charging and discharging control and the target SOC to an objective function and minimize the difference value through an optimization process of the set objective function. The second processing unit 112 may optimize the objective function by adapting a gradient descent method, a steepest descent method, or a stochastic gradient descent method.

The first charging and discharging schedules may follow a predetermined (e.g., desired) exit SOC input by a user who uses the V2X platform and identify the energy (e.g., required) for charging based on the SOC at the time of entry, the target SOC, and the battery capacity information of the electric vehicle.

The third processing unit 113 may calculate the second charging and discharging schedules for participation in the electric power market according to contracted power capacity data received from the demand management business operator server based on the first charging and discharging schedules. The third processing unit 113 may calculate the second charging and discharging schedules of the corresponding electric vehicle when contracted power capacity is present. The third processing unit 113 may calculate the second charging and discharging schedules to comply with the contracted power capacity for each time period. The second charging and discharging schedules may include second charging power and second discharging power. Here, the contracted power capacity may be determined according to previous day's bidding power, and the third processing unit 113 may sell electric power at a time when the electric power price is high and purchase power at a time when the electric power price is low using a predicted system marginal price (SMP) value as described herein and determine the bidding power to have maximizing profits.

The third processing unit 113 performs a function of calculating the second charging and discharging schedules when receiving the contracted power capacity based on the result of bidding in the renewable energy bidding market. The contracted power capacity (CPC) may include charging CPC and discharging CPC. The third processing unit 113 may calculate charging power and discharging power so that the corresponding CPC amount may be fully satisfied during the time period in which the CPC is present. In this case, the third processing unit 113 may calculate charging power and discharging power under the condition that the SOC of the electric vehicle follows the target SOC at the scheduled vehicle exit time. That is, the third processing unit 113 may calculate the charging power and discharging power of the electric vehicle according to the CPC, and when the target SOC cannot be followed at the scheduled vehicle exit time when the calculated charging and discharging power is applied, the calculated charging and discharging power amounts may be adjusted to follow the CPC.

That is, when the second charging power and the second discharging power do not satisfy the condition that they follow the target SOC, the third processing unit 113 may modify or discard the second charging and discharging schedules to adjust the second charging power and the second discharging power.

The third processing unit 113 may calculate the second charging and discharging schedules so that a total of the charging efficiencies is equal to a total of the discharging efficiencies. The third processing unit 113 may change parameters according to the electric power market rules. The third processing unit 113 may guide a total of the charging bid powers and a total of the discharging bid powers that are derived during a time period (e.g., 00:00 to 24:00 of the next day) available for bidding in the renewable energy bidding market to be balanced. In this case, the third processing unit 113 may bid considering charging and discharging efficiency and prevent loss of the battery charging amount of participating users. That is, the third processing unit 113 may calculate the second charging and discharging schedules so that a value obtained by multiplying the second charging power by charging efficiency is equal to a value obtained by multiplying the second discharging power by discharging efficiency. Accordingly, it may be possible to (e.g., effectively) prevent loss of the SOC of the electric vehicle that performs charging and discharging according to the second charging and discharging schedules.

The battery charging and discharging efficiency of the electric vehicle may be determined by various factors such as a composition material of a battery, a charging speed, control elements of a BMS, energy loss caused by electrical components such as cables, power converters, and/or the like. The charging and discharging efficiency refers to a ratio of energy lost during the process of storing electrical energy in a battery, and such loss may (e.g., mainly) occur in the form of heat loss.

When the charging and discharging scheduling is requested, the third processing unit 113 may generate charging and discharging schedule information that maximizes the objective function based on profits. The third processing unit 113 may set the charging and discharging schedules so that the profit through the sum of the charging fee and the discharging profit is maximized.

The third processing unit 113 may calculate the second charging and discharging schedules using the SMP.

The SMP may refer to an index that determines a price of power finally supplied in a specific time period in the electric power market. The third processing unit 113 may determine the SMP using a predicted power demand value and power plant bid power.

The third processing unit 113 sorts the bid power of the power plants that suggest the amount and price of power to be supplied in a specific time period in price order and accepts the bids sequentially from the lowest price until the amount of power (e.g., required) to meet the predicted power demand value is supplied. The third processing unit 113 may select a point at which demand matches supply and determine that the price of the (e.g., finally) accepted bid is the SMP. The determined price may represent the cost of supplying the final unit of power in the electric power system in a specific time period. The third processing unit 113 may set a combined cost of a cost of purchasing power for charging after charging/discharging control and a cost of selling power through discharging to the objective function using the predicted SMP and minimize a difference value through an optimization process of the set objective function.

The third processing unit 113 may optimize the objective function by adapting a gradient descent method, a steepest descent method, or a stochastic gradient descent method.

A processor according to the embodiment may sum plug-in times from a plurality of scheduled vehicle entry times to a plurality of scheduled vehicle exit times and calculate the first charging and discharging schedules and the second charging and discharging schedules according to the summed plug-in times. For example, when a specific electric vehicle is scheduled to enter and exit multiple times during a period in which a charging and discharging schedule is generated, the second processing unit 112 and the third processing unit 113 may sum plug-in times from the plurality of scheduled vehicle entry times to the plurality of scheduled vehicle exit times and generate the charging and discharging schedules. In this case, the second processing unit 112 may calculate the first charging and discharging schedules to follow the target SOC based on the summed plug-in times, and the third processing unit 113 may calculate the second charging and discharging schedules to follow the CPC amount based on the summed plug-in times.

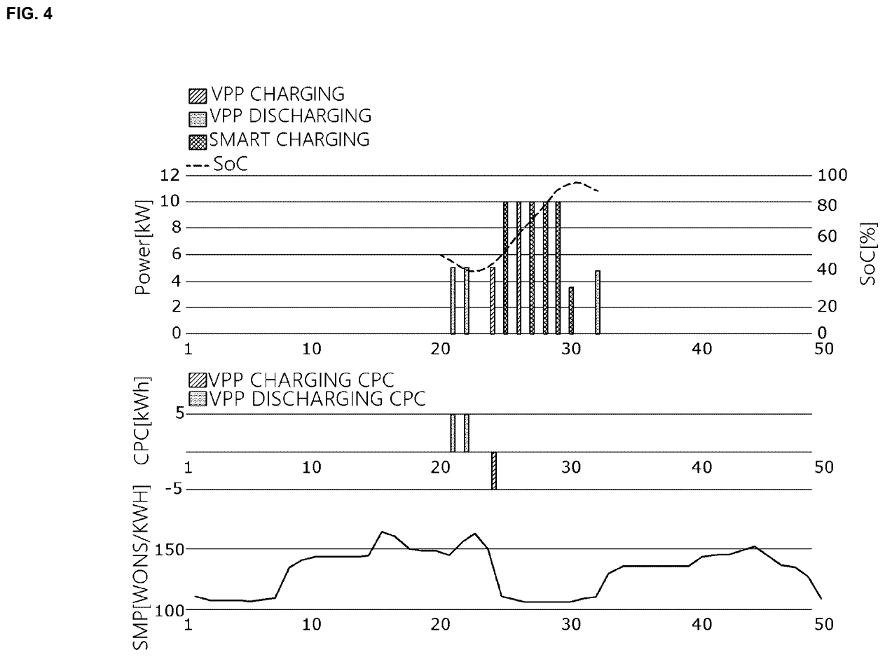

FIGS. 4, 5, and 6 are views for describing the operation of a processor according to the example embodiment.

Referring to FIG. 4, the result of scheduling the charging and discharging of an electric vehicle of which scheduled vehicle entry time is 19:00 and scheduled vehicle exit time is 32:00 is graphically illustrated. A current SOC of the electric vehicle at an entry time point is 50%, and the target SOC is 90%. The current SOC of the electric vehicle at the entry time point is within a preset battery usage range (e.g., 25% to 75%), and the maximum hourly charging energy considering the scheduled vehicle entry time and scheduled vehicle exit time is 10 [kWh], and the maximum discharging energy is 5 [kWh].

The processor performs charging at time points t=25, 27, 28, 29, and 30 and calculates the charging and discharging schedules to follow the target SOC at the scheduled vehicle exit time point. In addition, it can be confirmed that the processor sets charging or discharging power to follow the CPC amount at time points t=21, 22, and 24 when the CPC is present. The processor uses the predicted SMP value to maximize the profit generated by charging and discharging under the conditions of following the target SOC and calculates the schedule so that charging may be performed at the time point when the SMP is predicted to be the lowest.

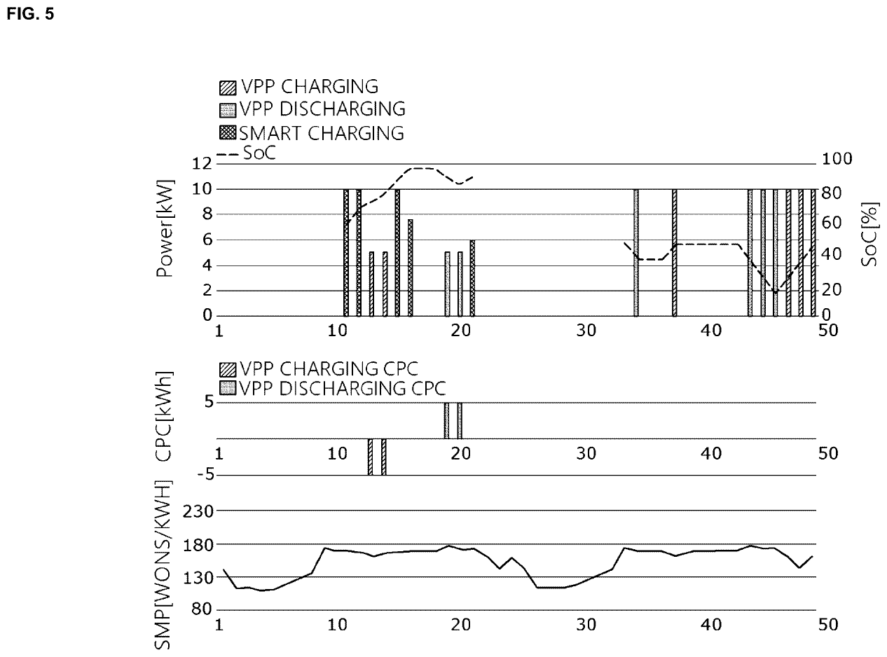

Referring to FIG. 5, the result of scheduling the charging and discharging of one electric vehicle with scheduled vehicle entry times of 11:00 and 34:00 and scheduled vehicle exit times of 21:00 and 48:00 is graphically illustrated. A current SOC of the electric vehicle at an entry time point is 50%, and the target SOC is 90%. The current SOC of the electric vehicle at the entry time point is within a preset battery usage range (e.g., 25% to 75%), and the maximum hourly charging energy considering the scheduled vehicle entry time and scheduled vehicle exit time is 10 [kWh], and the maximum discharging energy is 5 [kWh].

The processor performs charging at time points t=11, 12, 15, and 16 and calculates the charging and discharging schedules to follow the target SOC at the scheduled vehicle exit time point. In addition, it may be confirmed that the processor sets charging or discharging power to follow the CPC amount at time points t=13, 14, 19, and 20 when the CPC is present.

In addition, the processor calculates the bid power considering the time when the electric vehicle is plugged in during a period from 25:00 to 48:00, which is an available bid section. The processor may set the charging and discharging schedules to perform charging during a time period in which the SMP is predicted to be cheap and perform discharging during a time period in which the SMP is predicted to be relatively expensive based on the predicted SMP value.

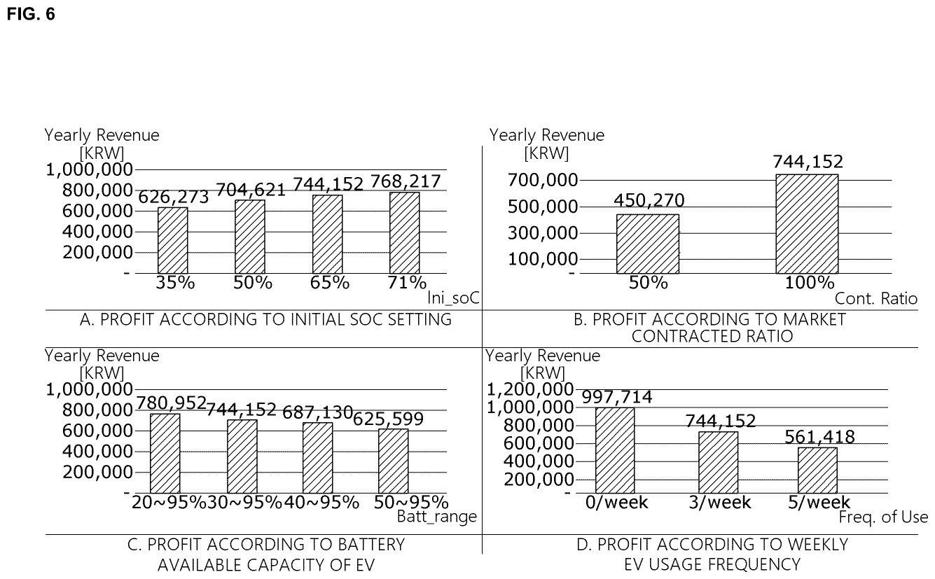

Referring to FIG. 6, the result of calculating an expected annual profit of electric vehicles that participate in the V2X algorithm according to a change in conditions can be confirmed.

Referring to Case A of FIG. 5, the graph discloses that the higher the current SOC at the entry time point of the electric vehicle, the higher the battery margin that can participate in the electric power trading market, and thus the expected profit is increased.

Referring to Case B of FIG. 5, =the graph discloses that the expected profit is increased as a ratio of the planned bid power to the CPC increases according to a market contracted ratio.

Referring to Case C of FIG. 5, this is the result of simulating the expected profits by setting the battery usage range to 75%, 65%, 55%, and 45% according to the battery capacity, and the graph discloses that the higher the battery usage range, that is, the higher the battery upper limit value, the more the participation in the electric power trading market increases, and the expected profit is increased.

Referring to Case D of FIG. 5, the graph discloses that the lower the weekly average usage frequency of an electric vehicle, the more the electric vehicle can be used as a fixed resource similar to an ESS, and thus the expected profit is increased.

The device for scheduling charging and discharging of an electric vehicle 100 according to the embodiment may independently perform various functions using a plurality of objective functions and constraint functions.

For example, the device for scheduling charging and discharging of an electric vehicle 100 may calculate a charging and discharging schedules according to an objective function that maximizes profits during the process of charging, discharging, and following the CPC. In this process, the processor 110 may set the following of the target SOC to a (e.g., top priority) objective function to calculate the first charging and discharging schedules and secondarily set the objective function to satisfy the CPC to calculate the second charging and discharging schedules. The processor 110 may reflect the target SOC and the CPC in the second charging and discharging schedules so that a total profit that sums the profit of the power sales (e.g., discharging) and the cost of the power purchase (e.g., charging) can be maximized using the predicted SMP value under the conditions that the target SOC and the CPC are followed.

When the SOC is out of the battery usage range, the processor 110 may calculate the first charging and discharging schedules so that the SOC of the electric vehicle is adjusted within the battery usage range with the highest priority.

In addition, the processor 110 may finally calculate the second charging and discharging schedules so that the total of charging efficiency is equal to the total of discharging efficiency, thereby preventing the occurrence of loss of the SOC during the electric power trading process.

When a plurality of entry and exit times are present, the processor 110 may calculate the first charging and discharging schedules to follow the target SOC that is set for each exit time and calculate the second charging and discharging schedules to comply with the CPC that is set for each time period. In addition, when the plurality of entry and exit times are present, the processor 110 may reflect the plurality of entry and exit times in the second charging and discharging schedules so that the profit of summing the profit of the power sales (e.g., discharging) and the cost of the power purchase (e.g., charging) during the total scheduling target period can be maximized.

Accordingly, it is possible to satisfy the battery SOC of the electric vehicle, which is the top priority goal in the V2X platform, and comply with the CPC in the electric power trading market as the second priority goal, thereby improving reliability. In addition, in a situation in which the top priorities are satisfied, profits generated by power sales and purchases can be maximized or expenditures can be minimized.

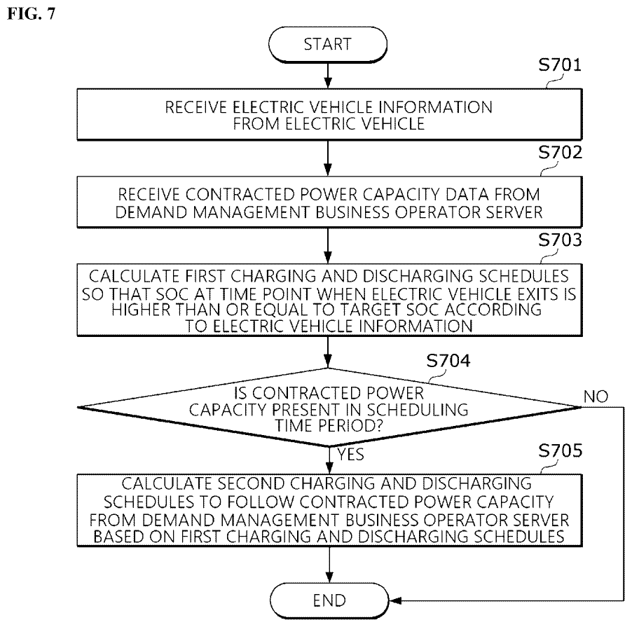

FIG. 7 is a flowchart illustrating a method of scheduling charging and discharging of an electric vehicle according to an embodiment.

First, a communication device receives electric vehicle information from an electric vehicle. The electric vehicle information includes plug-in charger information, a current SOC, a target SOC, resource type information, battery capacity information, and scheduled vehicle entry time and scheduled vehicle exit time information (S701).

Next, the communication device receives CPC data from a demand management business operator server (S702).

Next, the processor calculates first charging and discharging schedules so that an SOC at a time point when the electric vehicle exit is higher than or equal to a target SoC according to the electric vehicle information (S703).

Next, the processor determines whether a CPC is present in the CPC data in a scheduling time period (S704).

Next, when the CPC is present, the processor calculates second charging and discharging schedules to follow the CPC from the demand management business operator server based on the first charging and discharging schedules (S705).

The term “unit” used in the present embodiment means a software or hardware component such as an FPGA or an ASIC, and the “unit” performs (e.g., certain) roles. However, the “unit” is not limited to software or hardware. The “unit” may be formed to be disposed in an addressable storage medium and configured to reproduce one or more processors. Therefore, as an example, the “unit” is components such as software components, object-oriented software components, class components, and task components, processes, functions, attributes, procedures, subroutines, segments of program code, drivers, firmware, microcode, circuits, data, database, data structures, tables, arrays, and variables. Functions provided in the components and “units” may be combined into the smaller number of components and “unit” or separated into additional components and “units.” Additionally, the components and “units” may be implemented to reproduce one or more CPUs in a device or a security multimedia card.

A device and method for scheduling charging and discharging of an electric vehicle according to embodiments can establish and provide an optimal charging and discharging schedule according to requests (e.g., needs) of an electric vehicle.

In addition, it is possible to participate in an electric power trading market to generate profits using power of an electric vehicle.

Although the present disclosure has been described above with reference to example embodiments, those skilled in the art may understand that the present disclosure may be modified and changed variously without departing from the spirit and scope of the present disclosure as described in the appended claims.

What is claimed is:

1. An electrical vehicle control device for scheduling charging and discharging of an electric vehicle, comprising:
a memory storing computer-executable instructions; and
at least one processor configured to access the memory and execute the instructions, wherein the instructions comprise:
generating, via the processor, a first charging and discharging schedule, wherein a state of charge (SOC) at a time point when the electric vehicle exits is higher than or equal to a target SOC according to electric vehicle information;
generating, via the processor, a second charging and discharging schedule for participation of the electric vehicle in an electric power market according to contracted power capacity data received from a demand management business operator server based on the first charging and discharging schedule; and
charging the electric vehicle based on the first charging and discharging schedule or the second charging or discharging schedule.

2. The electrical vehicle control device of claim 1, wherein the electric vehicle information includes plug-in charger information, a current SOC, a target SOC, resource type information, battery capacity information, battery charging and discharging efficiency, and scheduled vehicle entry time and scheduled vehicle exit time information.

3. The electrical vehicle control device of claim 2, wherein the instructions further comprise calculating, via the processor, maximum hourly charging and discharging energy using output power included in the plug-in charger information and the scheduled vehicle entry time and the scheduled vehicle exit time.

4. The electrical vehicle control device of claim 2, wherein the instructions further comprise calculating, via the processor, the first charging and discharging schedule using the current SOC, the battery capacity information, and the target SOC of the electric vehicle.

5. The electrical vehicle control device of claim 2, wherein the instructions further comprise adjusting, via the processor, the SOC of the electric vehicle to be within a preset battery usage range and sets the first charging and discharging schedule.

6. The electrical vehicle control device of claim 2, wherein the instructions further comprise summing, via the processor, plug-in times from a plurality of scheduled vehicle entry times to a plurality of scheduled vehicle exit times, and calculating the first charging and discharging schedule and the second charging and discharging schedule according to the summed plug-in times.

7. The electrical vehicle control device of claim 1, wherein the instructions further comprise calculating, via the processor, the second charging and discharging schedule to comply with hourly contracted power capacity.

8. The electrical vehicle control device of claim 7, wherein the second charging and discharging schedule includes a schedule of charging power and discharging power.

9. The electrical vehicle control device of claim 8, wherein the instructions further comprise calculating, via the processor, the second charging and discharging schedule wherein a total of charging efficiencies is equal to a total of discharging efficiencies.

10. The electrical vehicle control device of claim 2, wherein the instructions further comprise calculating, via the processor, the first charging and discharging schedule and the second charging and discharging schedule to limit discharging according to the resource type information.

11. A method of scheduling charging and discharging of an electric vehicle, which is performed by a computing device, a memory storing computer-executable instructions, and at least one processor configured to access the memory and execute the instructions, the method comprising:
generating, by the processor, a first charging and discharging schedule wherein a state of charge (SOC) at a time point when the electric vehicle exits is higher than or equal to a target SOC according to electric vehicle information; and
generating, by the processor, a second charging and discharging schedule for participation in an electric power market according to contracted power capacity data received from a demand management business operator server based on the first charging and discharging schedule.

12. The method of claim 11, wherein the electric vehicle information includes plug-in charger information, a current SOC, a target SOC, resource type information, battery capacity information, battery charging and discharging efficiency, and scheduled vehicle entry time and scheduled vehicle exit time information.

13. The method of claim 12, wherein the generating of the first charging and discharging schedule includes calculating maximum hourly charging and discharging energy using output power included in the plug-in charger information and the scheduled vehicle entry time and the scheduled vehicle exit time.

14. The method of claim 12, wherein the generating of the first charging and discharging schedule includes calculating the first charging and discharging schedule using the current SOC, the battery capacity information, and the target SOC of the electric vehicle.

15. The method of claim 12, wherein the generating of the first charging and discharging schedule includes adjusting the SOC of the electric vehicle to be within a preset battery usage range and calculating the first charging and discharging schedule.

16. The method of claim 12, wherein the processor sums plug-in times from a plurality of scheduled vehicle entry times to a plurality of scheduled vehicle exit times and calculates the first charging and discharging schedule and the second charging and discharging schedule according to the summed plug-in times.

17. The method of claim 16, wherein the generating of the second charging and discharging schedule includes calculating the second charging and discharging schedule to comply with hourly contracted power capacity.

18. The method of claim 17, wherein the second charging and discharging schedule includes a schedule of charging power and discharging power.

19. The method of claim 18, wherein the generating of the second charging and discharging schedule includes calculating the second charging and discharging schedule so that a total of charging efficiencies is equal to a total of discharging efficiencies.

20. The method of claim 12, wherein the processor calculates the first charging and discharging schedule and the second charging and discharging schedule to limit discharging according to the resource type information.
